(19) United States
(12) Patent Application Publication
(10) Pub. No.: US 2010/0164890 A1
(43) Pub. Date: Jul. 1, 2010

(54) INPUT DEVICE FOR FLEXIBLE DISPLAY DEVICE AND MANUFACTURING METHOD THEREOF

(76) Inventors: Kyubok Lee, Seongnam-si (KR); Jaeyoung Lee, Suwon-si (KR); Jinsup Kim, Seongnam-si (KR); Sehwan Choi, Seongnam-si (KR)

Correspondence Address: North Star Intellectual Property Law, PC, P.O. Box 34688, Washington, DC, 20043, US

(21) Appl. No.: 12/644,267

(22) Filed: Dec. 22, 2009

(30) Foreign Application Priority Data
Dec. 26, 2008 (KR) 10-2008-0134553

(51) Int. Cl. G06F 3/041; H05K 3/00

(52) U.S. Cl. 345/173; 427/96.1

(57) ABSTRACT

A flexible input device having a bendability and an electrode that may be formed using a printing process is provided. The input device comprises a flexible and transparent substrate and a printed electrode on the substrate.

### CROSS-REFERENCE TO RELATED APPLICATIONS

This application claims the benefit under 35 U.S.C. §119(a) of a Korean Patent Application No. 10-2008-0134553, filed with the Korean Intellectual Property Office on Dec. 26, 2008, the entire disclosure of which is incorporated herein by reference for all purposes.

### BACKGROUND

1. Field

The following description relates to an input device for a flexible display and a manufacturing method thereof, and more particularly, to an input device and its manufacturing method that may be used in various flexible displays and a flexible display including such input device.

2. Description of the Related Art

Touch panels having a display, an input unit, and an information input for the display, have become popular in mobile terminals and devices. In a touch panel, information is inputted into a flat panel display by touching a screen, for example, using an input pen or a user's finger.

A resistive film method, a static capacitance method, surface acoustic wave (SAW) technology, and/or an infrared (IR) technology may be used for a touch panel. FIG. 1 illustrates a conventional resistive film type input device for a display.

The conventional input device for a display shown in FIG. 1 includes a bottom substrate 10, a top substrate 11, and a dielectric layer 12 that is used as a spacer. The dielectric layer 12 has a viscosity and is located between the bottom substrate 10 and the top substrate 11. A conductive material may be coated over the bottom substrate 10 and the top substrate 11. When a pressure is applied to the top substrate 10, the conductive materials of the top substrate 11 and the bottom substrate 10 may touch each other, and therefore the X and Y coordinates of the position of the touch may be measured.

FIG. 2A illustrates a bent conventional input device for a display, and FIG. 2B illustrates a touched portion of an input device when a flat panel type display input device is bent. Referring to FIG. 2A and FIG. 2B, the top substrate 21, the bottom substrate 20, and the dielectric layer 22 may be bent as shown in FIG. 2A. The top substrate 21 and the bottom substrate 20 are spaced apart with a dielectric layer 22 in between them. The top substrate 21 and the bottom substrate 20 may touch in a region such as A as shown in FIG. 2B.

When a conventional input device for a display is used in a flexible display instead of a flat type display, an operation error may occur by touching between a top substrate 21 and a bottom substrate 20, even in an untouched state.

When a conventional input device is used in a flexible display, problems may occur, for example, a lack of flexibility of the substrate itself or an input error due to an unnecessary contact between the substrates of the bent input device.

### SUMMARY

In one aspect, provided is a flexible display input device comprising a flexible transparent substrate, and an electrode printed on the substrate.

The transparent substrate may include at least one of an indium tin oxide (ITO) substrate, a plastic substrate, and a dielectric substrate.

The transparent substrate may comprises a plastic substrate that may include at least one of a polyester (PET) film, a polyethylenenaphthalate (PEN) film, a polycarbonate (PC) film, a polyetherimide film, and a polyethersulfone (PES) film.

The electrode may include a conductive ink.

The conductive ink may include at least one of a silver (Ag) powder, a gold (Au) powder, a nickel (Ni) powder, and a copper (Cu) powder.

The conductive ink may includes conductive organic polymer.

The conductive organic polymer may include at least one of a polypyrrole, polyaniline, polyacetylene, polythiophene, polyphenylene vinylene, polyphenylene sulfide, poly p-phenylene, and polyheterocycle vinylene.

The flexible display input device may be an input device for at least one of a mobile terminal, a game machine, an e-paper, and a wearable computer.

In another aspect, provided is a method for manufacturing an input device for a flexible display, the method comprising preparing a flexible transparent substrate, and electrode forming a conductive ink on the substrate.

The electrode forming may include printing a mixture of a binder, a solvent, and at least one of a silver (Ag) powder, a gold (Au) powder, a nickel (Ni) powder, and a copper (Cu) powder.

In another aspect, provided is a flexible display apparatus comprising a flexible transparent substrate, an input unit comprised of an electrode printed on the transparent substrate, and a flexible display unit.

The input unit may be located on a top surface or a bottom surface of the display unit.

The transparent substrate may include at least one of an indium tin oxide (ITO) substrate, a plastic substrate, and a dielectric substrate.

The plastic substrate may include at least one of a polyester (PET) film, a polyethylenenaphthalate (PEN) film, a polycarbonate (PC) film, a polyetherimide film, and a polyethersulfone (PES) film.

The electrode may include a conductive ink.

The conductive ink may include at least one of a silver (Ag) powder, a gold (Au) powder, a nickel (Ni) powder, and a copper (Cu) powder.

The conductive ink includes a conductive organic polymer.

The conductive organic polymer may include at least one of a polypyrrole, polyaniline, polyacetylene, polythiophene, polyphenylene vinylene, polyphenylene sulfide, poly p-phenylene, and polyheterocycle vinylene.

The flexible display apparatus may be at least one of a mobile terminal, a game machine, an e-paper, and a wearable computer.

Other features and aspects will be apparent from the following detailed description, the drawings, and the claims.

### BRIEF DESCRIPTION OF THE DRAWINGS

FIG. 1 is a diagram illustrating a conventional resistive film type input device for a display.

FIG. 2A is a diagram illustrating a bent conventional input device for a display, and FIG. 2B is a diagram illustrating a touched portion of a conventional input device.

FIG. 3 is a diagram illustrating an example of an input device for a flexible display.

FIG. 4 is a diagram illustrating an example of a bent input device for a display.

FIG. 5 is a diagram illustrating an example of an input device for a flexible display and an input unit.

FIG. 6 is a diagram illustrating a flexible display including an input device.

FIG. 7 is a diagram illustrating an example of a multimedia apparatus equipped with a flexible display.

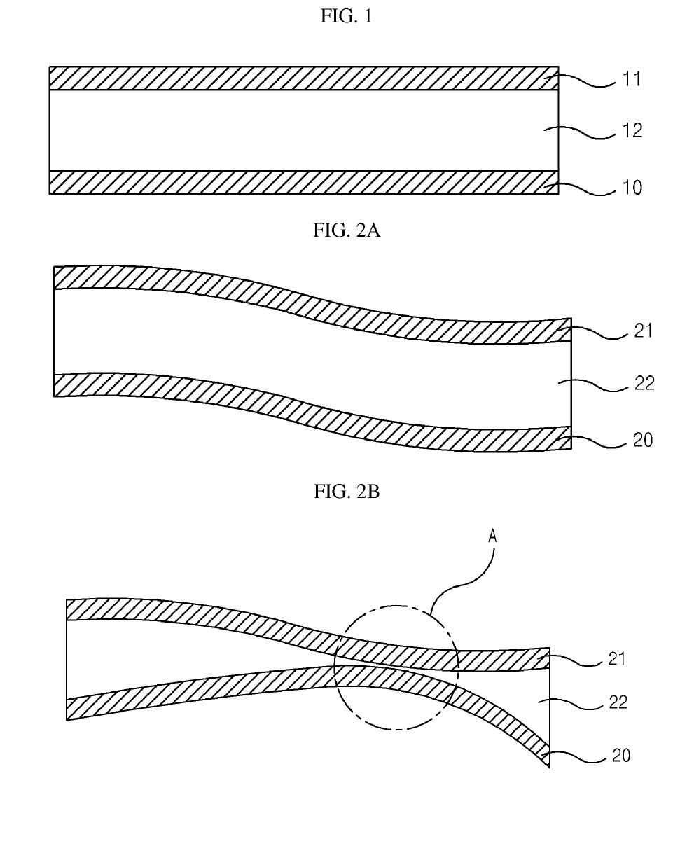

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

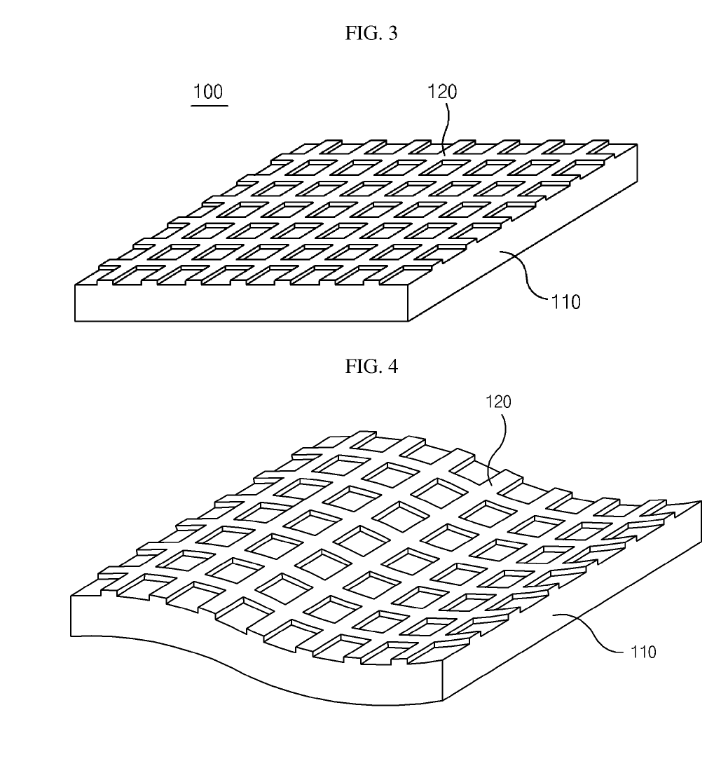

FIG. 3 illustrates an example of an input device for a flexible display. The example input device 100 includes a flexible transparent substrate 110 and an electrode 120 printed on the substrate 110.

The transparent substrate 110 may be made from various materials, for example, at least one of an indium tin oxide (ITO), a plastic, or a dielectric. The substrate 110 is a flexible transparent substrate and it may be used for a flexible display.

Substrate 110 may include a metal oxide having transparent characteristics. For example, the metal oxide may be an ITO substrate, an indium zinc oxide (IZO) substrate, and the like.

Substrate 110 may include a plastic substrate, for example, at least one of a polyester (PET) film, a polyethylenenaphthalate (PEN) film, a polycarbonate (PC) film, a polyetherimide film, a polyethersulfone (PES) film, and the like.

The electrode 120 printed on a substrate 110 shown in FIG. 3 is illustrated as a grid shape. However, the electrode 120 is not limited to this. The electrode 120 may be implemented in various forms. In some embodiments the electrode 120 may be implemented according to the electrode connections.

The electrode 120 may be printed using a conductive ink. The conductive ink may include a metal powder, for example, at least one of a silver (Ag) powder, a gold (Au) powder, a nickel (Ni) powder, a copper (Cu) powder, and the like. The conductive ink may be applied in a printing process through mixing of nano-powder of above-mentioned metals with a solvent or a binder.

The conductive ink may include a conductive organic polymer. The conductive organic polymer may include, for example, at least one of a polypyrrole, polyaniline, polyacetylene, polythiophene, polyphenylene vinylene, polyphenylene sulfide, poly p-phenylene, and polyheterocycle vinylene.

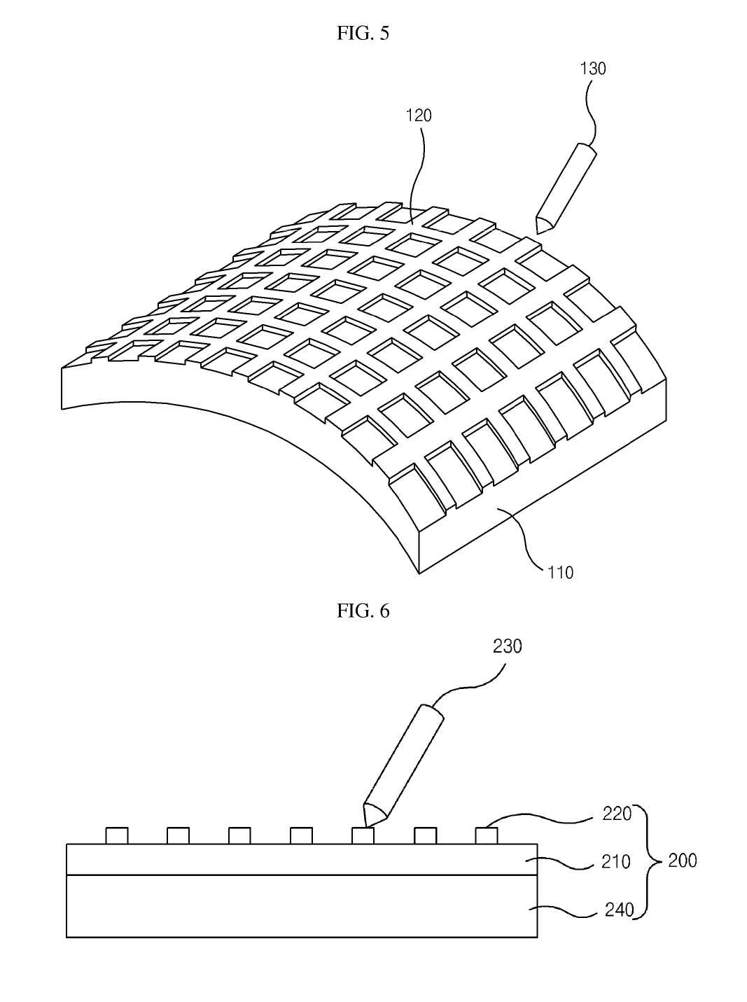

FIG. 4 illustrates an example of a bent input device for a display. FIG. 5 illustrates an example of an input device for a flexible display and an input unit.

Referring to FIG. 4, because the input device 100 has a flexible substrate 110, and the electrode 120 is printed on a flexible substrate, the input device 100 may be bent or have a curvature as shown in FIG. 4. Referring to FIG. 5, because the electrode 120 is printed on the substrate 110, desired data may be accurately inputted using an input tool 130 even though the input device is bent.

The input device 100 may be used in a flexible display, for example, in a mobile phone, a game machine, an e-paper, a wearable computer, and the like.

A manufacturing method of an input device for a flexible display is also provided. The manufacturing method includes preparing a flexible and transparent substrate, and forming an electrode by printing a conductive ink on a substrate.

The electrode may be performed by printing a metal powder, for example, at least one of a silver (Ag) powder, a gold (Au) powder, a nickel (Ni) powder, a copper (Cu) powder, and the like, with a mixture of solvents on a substrate. The electrode may be formed by printing on a substrate using a mixture including a conductive organic polymer instead of the above-described metal powder. The input device 100 may be implemented by forming an electrode more simply through a direct printing of a mixture on a substrate.

An inkjet printing, an aerosol printing, or a dispensing method may be used for an electrode printing. As described above, a metal powder or a mixture including a conductive organic polymer may be printed on a substrate so as to form an electrode pattern. The solvent may be evaporated through a drying process.

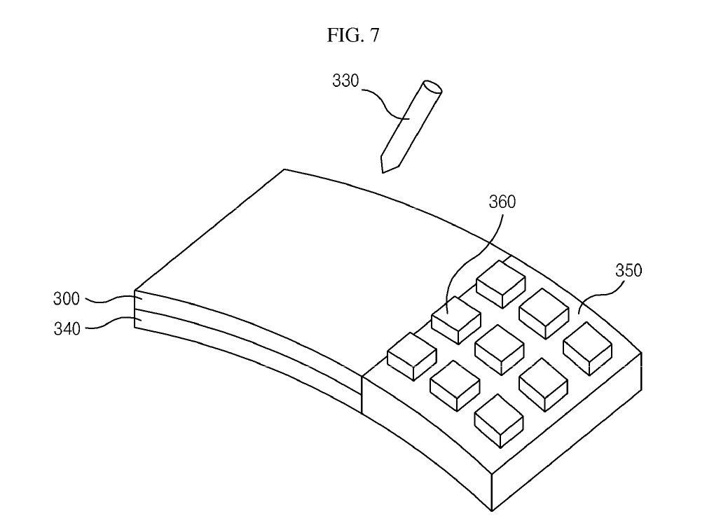

FIG. 6 illustrates an example of a flexible display including an input device. The flexible display may be, for example, the flexible display illustrated in FIG. 3. Flexible display 200 includes a flexible transparent substrate 210, an input unit which includes an electrode 220 printed on a transparent substrate 210, and a flexible display unit 240.

For example, an input unit may be located either on a top surface or on a bottom surface of the display unit 240. When the input unit is located on the top surface of the display unit 240, data may be directly inputted into the display screen. When the input unit is located on the bottom surface of the display unit 240, data may be inputted into the input unit located on the bottom surface, and then the inputted data may be received and displayed by the display unit 240.

FIG. 7 illustrates an example of a multimedia apparatus equipped with a flexible display. An example multimedia apparatus equipped with a flexible display device includes an input unit 300 and a display unit 340. The multimedia apparatus may be, for example, a mobile terminal, a computer, a game machine, an e-paper, a wearable computer, and the like.

For example, a mobile terminal may be made from a flexible material that may be mounted on a curved location such as an arm, a shoulder, and the like. For example, a body 350 of the multimedia apparatus and/or the key pad 360 may be manufactured to have an appropriate curvature, and a flexible multimedia apparatus may be manufactured by coupling a flexible display into the body 350.

In some embodiments, when only a display portion is flexible but a body or a key pad is generally non-flexible, then the display portion may be mounted on a human body.

Therefore, an input device for a flexible display may be used in a flexible display and may be evolved into a wearable type or a curved surface mounting. This type of input device may reduce potential errors that are caused in conventional display input devices.

As a non-exhaustive illustration only, the terminal device described herein may refer to mobile devices such as a cellular phone, a personal digital assistant (PDA), a digital camera, a portable game console, and an MP3 player, a portable/personal multimedia player (PMP), a handheld e-book, a portable lab-top PC, a global positioning system (GPS) navigation, and devices such as a desktop PC, a high definition television (HDTV), an optical disc player, a setup box, and the like capable of wireless communication or network communication consistent with that disclosed herein.

A computing system or a computer may include a microprocessor that is electrically connected with a bus, a user interface, and a memory controller. It may further include a flash memory device. The flash memory device may store N-bit data via the memory controller. The N-bit data is processed or will be processed by the microprocessor and N may be 1 or an integer greater than 1. Where the computing system or computer is a mobile apparatus, a battery may be additionally provided to supply operation voltage of the computing system or computer.

It will be apparent to those of ordinary skill in the art that the computing system or computer may further include an application chipset, a camera image processor (CIS), a mobile Dynamic Random Access Memory (DRAM), and the like. The memory controller and the flash memory device may constitute a solid state drive/disk (SSD) that uses a non-volatile memory to store data.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A flexible display input device comprising:
a flexible transparent substrate; and
an electrode printed on the substrate.

2. The flexible display input device of claim 1, wherein the transparent substrate includes at least one of an indium tin oxide (ITO) substrate, a plastic substrate, and a dielectric substrate.

3. The flexible display input device of claim 2, wherein the transparent substrate comprises a plastic substrate including at least one of a polyester (PET) film, a polyethylenenaphthalate (PEN) film, a polycarbonate (PC) film, a polyetherimide film, and a polyethersulfone (PES) film.

4. The flexible display input device of claim 1, wherein the electrode includes a conductive ink.

5. The flexible display input device of claim 4, wherein the conductive ink includes at least one of a silver (Ag) powder, a gold (Au) powder, a nickel (Ni) powder, and a copper (Cu) powder.

6. The flexible display input device of claim 4, wherein the conductive ink includes a conductive organic polymer.

7. The flexible display input device of claim 6, wherein the conductive organic polymer includes at least one of a polypyrrole, polyaniline, polyacetylene, polythiophene, polyphenylene vinylene, polyphenylene sulfide, poly p-phenylene, and polyheterocycle vinylene.

8. The flexible display input device of claim 1, wherein the flexible display input device is an input device for at least one of a mobile terminal, a game machine, an e-paper, and a wearable computer.

9. A method for manufacturing an input device for a flexible display, the method comprising:
preparing a flexible transparent substrate; and
electrode forming a conductive ink on the substrate.

10. The method of claim 9, wherein the electrode forming includes printing a mixture of a binder, a solvent, and at least one of a silver (Ag) powder, a gold (Au) powder, a nickel (Ni) powder, and a copper (Cu) powder.

11. A flexible display apparatus comprising:
a flexible transparent substrate;
an input unit comprised of an electrode printed on the transparent substrate; and
a flexible display unit.

12. The flexible display apparatus of claim 11, wherein the input unit is located on a top surface or a bottom surface of the display unit.

13. The flexible display apparatus of claim 11, wherein the transparent substrate includes at least one of an indium tin oxide (ITO) substrate, a plastic substrate, and a dielectric substrate.

14. The flexible display apparatus of claim 13, wherein plastic substrate includes at least one of a polyester (PET) film, a polyethylenenaphthalate (PEN) film, a polycarbonate (PC) film, a polyetherimide film, and a polyethersulfone (PES) film.

15. The flexible display apparatus of claim 11, wherein the electrode includes a conductive ink.

16. The flexible display apparatus of claim 15, wherein the conductive ink includes at least one of a silver (Ag) powder, a gold (Au) powder, a nickel (Ni) powder, and a copper (Cu) powder.

17. The flexible display apparatus of claim 15, wherein the conductive ink includes a conductive organic polymer.

18. The flexible display apparatus of claim 17, wherein the conductive organic polymer includes at least one of a polypyrrole, polyaniline, polyacetylene, polythiophene, polyphenylene vinylene, polyphenylene sulfide, poly p-phenylene, and polyheterocycle vinylene.

19. The flexible display apparatus of claim 11, wherein the flexible display apparatus is at least one of a mobile terminal, a game machine, an e-paper, and a wearable computer.
